(19) United States
(12) Patent Application Publication
(10) Pub. No.: US 2006/0006375 A1
(43) Pub. Date: Jan. 12, 2006

(54) Light Mixing LED

(76) Inventors: Chen Ou, HsinChu (TW); Chen-Ke Hsu, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/162,562

(22) Filed: Sep. 14, 2005

Related U.S. Application Data
(63) Continuation-in-part of application No. 10/412,306, filed on Apr. 14, 2003, now abandoned.

(51) Int. Cl. H01L 29/06

(52) U.S. Cl. 257/14

(57) ABSTRACT

A light mixing LED includes a first active layer containing In laminated adjacent to an n-type nitride-based semiconductor stack layer, a second active layer containing In laminated adjacent to a p-type nitride-based semiconductor stack layer, and a tunnelable barrier layer formed between the first active layer and the second active layer.

### CROSS REFERENCE TO RELATED APPLICATIONS

This is a continuation-in-part of application Ser. No. 10/412,306, filed Apr. 14, 2003, which is incorporated in its entirety herein by reference.

### BACKGROUND OF THE INVENTION

1. Field of the Invention

The present invention generally relates to a light emitting diode (LED), and more particularly to a light mixing LED.

2. Description of the Prior Art

Light emitting diodes (LEDs) are employed in a wide variety of applications including optical displays, traffic lights, data storage apparatuses, communication devices, illumination apparatuses, and medical treatment equipment. Among varieties of LEDs, white LEDs are the most important and are in great demand. Fluorescent tubes or lamps that are widely used could be replaced by white LEDs if the manufacturing cost thereof can be reduced and the life thereof can be prolonged.

In conventional, three individual LEDs, such as a red LED, green LED, and blue LED, can be combined to generate a light mixing and form a white light emitting device. However, the production cost of such light emitting device is high, and the effect of the light mixing is not optimal because the three individual LEDs are not small enough to form a spot light.

The prior art also provides a white LED by using a single LED chip together with a yellow phosphor. However, the lifetime of the yellow phosphor is much shorter than that of the blue LED chip, thus limiting the lifetime of the white LED.

Japanese Patent Publication No. 11-87773, disclosed a light mixing white LED chip comprising multiple active layers having different energy bandgaps for emitting color lights with different wavelengths, so as to generate mixed light of a broad emission spectrum. As shown in FIGS. 1, 2, and 3, quantum well layers in active layers have different energy bandgaps, and are separated by barrier layers having different energy bandgaps. Also, the energy bandgap of a barrier layer adjacent to a p-type GaN side is smaller (or 20% smaller) than that of a barrier layer adjacent to an n-type GaN side, while an energy bandgap of a quantum well layer adjacent to the n-type GaN side is larger than that of a quantum well layer adjacent to the p-type GaN side. In other words, the wavelength of light emitted from an active layer adjacent to the n-type GaN side is shorter than that from an active layer adjacent to the p-type GaN side, causing an overflow effect of conductive carriers, and resulting in coincidence luminescence from the quantum well layers. Therefore, mixed light of a broad emission spectrum can be generated.

However, thicknesses of the barrier layers and the quantum well layers must be very thin (1 nm-2 nm) in the LED chip as disclosed in JP 11-87773. Such thin barrier layers cannot confine the conductive carriers effectively, so the luminance efficiency is inferior. In addition, if color of the mixed light generated by the LED chips different from the predetermined color, it is hard to adjust wavelengths and intensities of light generated by the quantum well layers because the color and the color rendering index property of the mixed light are related to plenty of parameters (which are complex to analyze), such as compositions, energy bandgaps, and widths of the quantum well layers and of the barrier layers. Besides, JP 11-87773 disclosed doping p-type dopants into the quantum well layers and the barrier layers of the LED chip, which affects the luminance effect. As a result, the technique disclosed in JP 11-87773 cannot be utilized for mass production.

U.S. Pat. No. 6,163,038, disclosed another light mixing LED chip, wherein a mixed light or white light, consisting different color lights of different wavelengths, is emitted from epitaxial active layers. Adjusting the LED chip disclosed in U.S. Pat. No. 6,163,038 is much easier because the LED chip comprises only two or three active layer corresponding to different colors. Therefore, the mixed light having predetermined wavelengths can be achieved by adjusting epitaxial parameters, such as the temperature, pressure, flowrate of ammonia, proportion of a carrier gas, and/or doped magnesium or silicon.

Please refer to FIG. 4, which illustrates a schematic diagram of an LED chip 400 in accordance with U.S. Pat. No. 6,163,038. The LED chip 400 includes two quantum well structures for emitting two color lights, which are a first active layer set 402 and a second active layer set 404. By adjusting the above-mentioned epitaxial parameters, the first active layer set 402 adjacent to an n-type semiconductor side 406 emits yellow light with wavelengths from about 550 to 620 nm, while the second active layer set 404 adjacent to a p-type semiconductor side 408 emits blue light with wavelengths from about 370 to 550 nm. In the first and second active layer sets 402 and 404, a quantum well layer is sandwiched between two barrier layers, which are formed by materials according to the required color of light to be emitted from the quantum well layer. The thicknesses of the barrier layers are 5-100 nm, so the total thickness between the quantum well layers of the first and second active layer sets 402 and 404 is 10-200 nm.

In the LED chip 400, intensities of yellow or blue lights are adjusted to get a specific color rendering coordinate by increasing or deceasing pair numbers of corresponding active layers. However, the above adjustment, by increasing or deceasing pair numbers of corresponding active layers, cannot get a continuous color rendering coordinate, i.e. the LED chip 400 is hard to be fine-tuned to change the color rendering coordinate thereof.

The above problem has been disclosed in U.S. Pat. No. 6,608,330 (referring to FIG. 3 thereof), describing that after decreasing a pair of active layer emitting blue light, a color rendering coordinate is changed from (0.333,0.314) to about (0.21,0.23), so the change of color rendering coordinate is great. More specifically, U.S. Pat. No. 6,608,330 disclosed a structure of active layers: an active layer set adjacent to an n-type semiconductor side emits blue light with wavelengths from about 450 to 500 nm, and an active layer set adjacent to a p-type semiconductor side emits yellow light with wavelengths from about 560 to 670 nm. Then, by adjusting the pair number of the active layer sets, the thickness of a barrier layer between the active layer sets, or a roughness degree of a quantum well layer of yellow light, and then intensity ratio between yellow and blue lights can be finally adjusted to get a predetermined color rendering coordinate.

Therefore, to generate a mixed white light is practicable in accordance with U.S. Pat. No. ______. However, in U.S. Pat. No. 6,608,330, the thickness of the barrier layer between the two different color active layers has an order of around hundred angstroms, i.e. the thickness of the barrier layer between the active layer sets can only be changed from 250 to 200 angstroms or from 250 to 300 angstroms, so that changing the thickness of the barrier layer can only fine-tune the color rendering coordinate in a narrow thickness range of the barrier layer. As a result, if a mixed light of non-white light is required, a designer must consider three parameters at the same time, including pair numbers of the active layer sets, the thickness of the barrier layer, and the roughness degree of the quantum well layer. Too many parameters are too complex to control.

In addition, the structure disclosed in U.S. Pat. No. 6,608,330 has another disadvantage. That is, a quantum well of blue light with a short wavelength (near a substrate) is below a quantum well (near a top surface) of yellow light with a long wavelength, so that blue light emitted to the top surface will be absorbed by the quantum well of yellow light. As a result, another parameter, i.e. a roughness degree in the quantum well of yellow light, should be considered.

Therefore, in the prior arts, a designer must adjust at least two or three parameters to control the intensity ratio of different color lights. The prior art chip can be rough-tuned firstly and then fine-tuned to achieve a color rendering coordinate. However the method mention above is uncontinuous and inaccurate, which is too complex and inefficient for mass production.

Therefore, a method for simply, effectively and accurately adjusting the intensity ratio between different color lights plays an important role for achieving a predetermined color rendering coordinate.

### SUMMARY OF THE INVENTION

It is therefore an object of the present invention to provide a light mixing LED capable of adjusting color of a mixed light by changing a thickness of a tunnelable barrier layer to achieve a predetermined color rendering coordinate.

According to this invention, a light mixing LED comprises an n-type nitride-based semiconductor stack layer, a p-type nitride-based semiconductor stack layer, and multiple active layers of quantum well structure sandwiched between the n-type nitride-based semiconductor stack layer and the p-type nitride-based semiconductor stack layer. The multiple active layers comprises a first active layer containing In laminated adjacent to the n-type nitride-based semiconductor stack layer, a second active layer containing In laminated adjacent to the p-type nitride-based semiconductor stack layer, and a tunnelable barrier layer formed between the first active layer and the second active layer. A first principal peak wavelength of light emitted from the first active layer is longer than a second principal peak wavelength of light emitted from the second active layer. A color rendering coordinate of a mixed light in a chromaticity diagram is set at a predetermined value in a range between that of the first principal peak wavelength and that of the second principal peak wavelength substantially in proportion to a thickness of the tunnelable barrier layer.

These and other objects of the present invention will become obvious to those of ordinary skill in the art after reading the following detailed description of the preferred embodiment that is illustrated in the accompanying drawings.

### BRIEF DESCRIPTION OF THE DRAWINGS

FIG. 1 illustrates a schematic diagram of a prior art light mixing LED.

FIGS. 2 and 3 illustrate character diagrams of the light mixing LED as shown in FIG. 1.

FIG. 4 illustrates a schematic diagram of a prior art light mixing LED.

FIG. 5 illustrates a schematic diagram of holes tunneling through a tunnelable barrier layer.

FIG. 6 illustrates a schematic diagram of a light mixing LED in accordance with a preferred embodiment of the present invention.

FIG. 7 illustrates a chromaticity chart corresponding to thicknesses of a tunnelable barrier layer.

FIGS. 8 to 11 illustrate diagrams of intensities of green light and blue light corresponding to thicknesses of a tunnelable barrier layer.

FIG. 12 illustrates a diagram of peak wavelengths of green and blue lights corresponding to the thickness of a tunnelable barrier.

FIG. 13 illustrates a schematic diagram of a light mixing LED in accordance with a preferred embodiment of the present invention.

FIG. 14 illustrates a diagram of intensity of blue and yellow lights corresponding to the thickness of a tunnelable barrier of a light mixing LED.

FIG. 15 illustrates a chromaticity chart corresponding to different thicknesses of a tunnelable barrier layer.

FIG. 16 illustrates a schematic diagram of a three-color light mixing LED of in accordance with a preferred embodiment of the present invention.

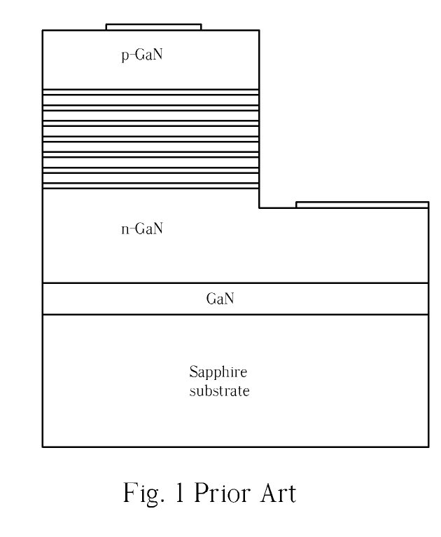

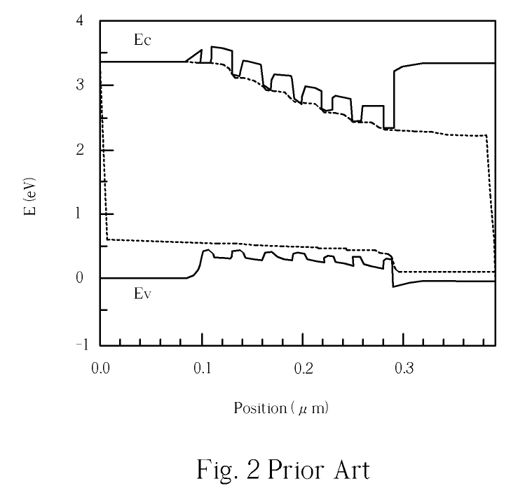

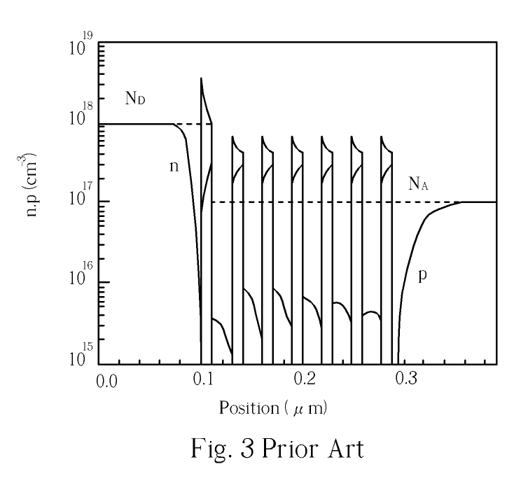

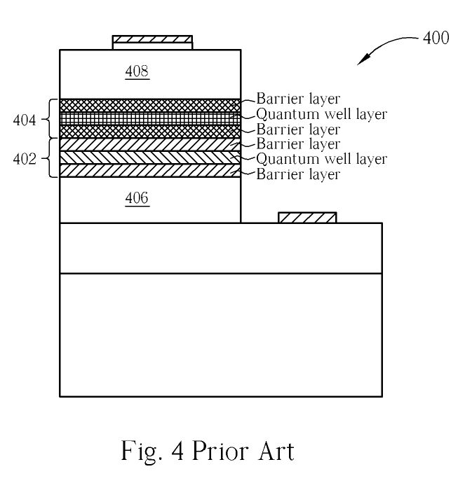

### DETAILED DESCRIPTION OF THE INVENTION

The present invention decreases complexity of manufacturing a light mixing white LED by forming a tunnelable barrier layer between two active layers of two color lights, and a color rendering coordinate of a mixed light generated by the light mixing white LED can be adjusted continuously and easily in a wide range. In a design of an epitaxial structure, after selecting wavelengths of active layers corresponding to two (or three) colors, a tunnelable barrier layer is formed between the active layers. Then, by adjusting a width of the tunnelable barrier layer, the tunneling probability of conductive carriers passing through the tunnelable barrier layer is changed, and a distribution ratio of conductive carriers in an electro-photo energy conversion is changed accordingly. As a result, intensities of two primary peaks can be adjusted to control a color rendering coordinate continuously and in a wide range.

As those skilled in the art can understand, in a nitride-based semiconductor, carrier concentration, mobility, and diffusion length of hole in p-type semiconductor (named holes) are much lower than those of electrons in n-type semiconductor, so recombination for light generation is limited by the holes. Therefore, in an active layer of a nitride-based LED, a region adjacent to a p-type semiconductor side semiconductor has much better luminance efficiency than a region adjacent to an n-type semiconductor side semiconductor.

So, controlling density of holes in quantum wells can be used to determine the individual luminance efficiencies of the quantum wells as well as the intensity ratio of the different color lights. Therefore, the present invention provides a nitride-based light mixing LED, which comprises an insulating substrate, a buffer layer formed over the insulating substrate, a first nitride semiconductor stack comprising at least one n-type contact layer formed over the buffer layer, the n-type contact layer having a first surface region and a second surface region, at least one first active layer of quantum well formed over the first surface region, a tunnelable barrier layer formed over the first active layer of quantum well, a second active layer of quantum well formed over the tunnelable barrier layer, a p-type cladding layer formed over the second quantum well active layer, a p-type contact layer formed over the p-type cladding layer, a transparency contact layer formed over the p-type contact layer, a second electrode formed over the transparency contact layer, an ohmic metal contact layer formed over the second surface region of the n-type contact layer, and a first electrode formed over the ohmic metal contact layer.

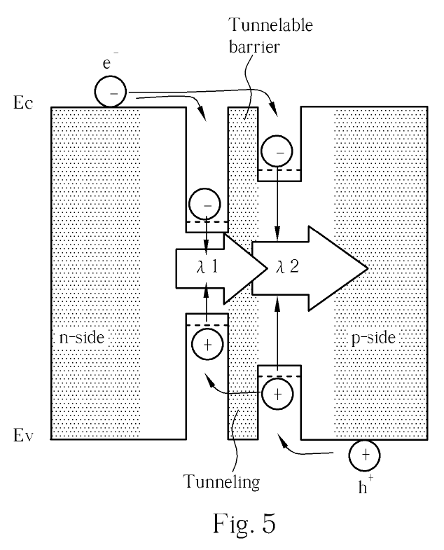

In accordance with the present invention, the density ratio of holes in a well of the first active layer and holes in a well of the second active layer is changed according to tunneling probability of the tunnelable barrier layer as well as its thickness, so that an energy bandgap of the well of the first active layer adjacent to the n-type semiconductor side must be smaller than that of the well of the second active layer adjacent to the p-type semiconductor side. A first principal peak wavelength of light emitted from the well of the first active layer is longer than a second principal peak wavelength of light emitted from the well of the second active layer. As a result, the tunnelable barrier layer plays a role in adjusting the density ratio of holes in the active layers as shown in FIG. 5.

Referring to FIG. 5, by adjusting the width of a tunnelable barrier layer, amounts of holes, injecting into the well of the second active layer and recombining with electrons for generating a second color. Then the holes tunneling through the tunnelable barrier layer to the well of the first active layer and recombining with electrons in the well of the first active layer for generating a first color in the first quantum well active layer, can be controlled. That is the density ratio of holes in the well of the first active layer and in the well of the second active layer can be predetermined by the width of the tunnelable barrier layer. In order to achieve the tunneling phenomenon, the well of the first active layer must provide an available energy level for tunneled holes occupying. This is the reason why the energy bandgap of the well of the first active layer must be smaller than that of the well of the second active layer. On the other hands, the well of the first active layer deeper than that of the well of the second active layer is necessary.

Therefore, when adjusting color of the mixed light in accordance with the present invention, a thickness of the tunnelable barrier layer is increased to change the wavelength of the mixed light to a shorter wavelength, or the thickness is decreased to change the wavelength of the mixed light to a longer wavelength. In other words, there is only one parameter (the thickness of the tunnelable barrier layer) to be considered, and the color rendering coordinate of the mixed light can be easily and continuously adjusted in a wide range of a color rendering coordinate. Therefore, the manufacturing of a light mixing white LED can be simplified in accordance with the present invention.

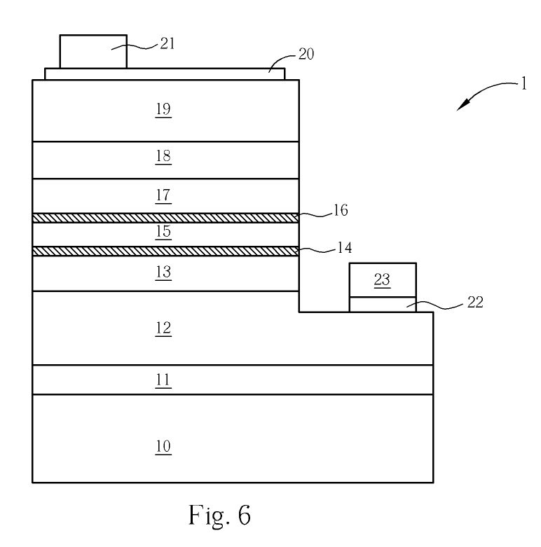

Referring to FIG. 6, the light mixing LED 1 comprises a sapphire substrate 10, a GaN buffer layer 11 formed over the sapphire substrate 10, a Si-doped GaN n-type contact layer 12 formed over the buffer layer 11 comprising a first surface region and a second surface region, an ohmic metal contact layer 22 formed over the second surface region of the n-type contact layer 12, a first electrode pad 23 formed over ohmic metal contact layer 22, a first GaN barrier layer 13 formed over the first surface region of the n-type contact layer 12, a first InGaN quantum well active layer 14 formed over the first GaN barrier layer 13, an unintentionally doped GaN tunnelable barrier layer 15 formed over the first InGaN quantum well active layer 14, a second InGaN quantum well active layer 16 formed over the GaN tunnelable barrier layer 15, a second GaN barrier layer 17 formed over the second InGaN quantum well active layer 16, a Mg-doped AlGaN p-type cladding layer 18 formed over the second GaN barrier layer 17, a Mg-doped GaN p-type contact layer 19 formed over the Mg-doped AlGaN p-type cladding layer 18, a transparency contact layer 20 formed over the Mg-doped GaN p-type contact layer 19, and a second electrode pad 21 formed over the transparency contact layer 20.

In the light mixing LED 1, an undoped GaN layer can be inserted between the GaN buffer layer 11 and the Si-doped GaN n-type contact layer 12, and a Si-doped AlGaN n-type cladding layer can be inserted between the Si-doped GaN n-type contact layer 12 and the first GaN barrier layer 13.

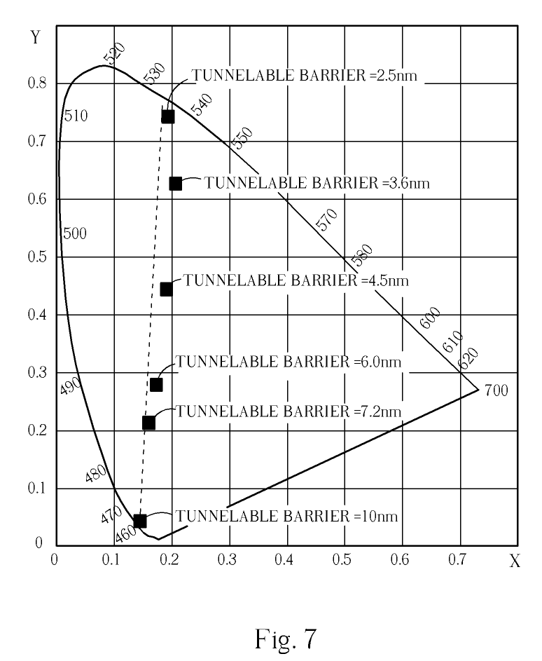

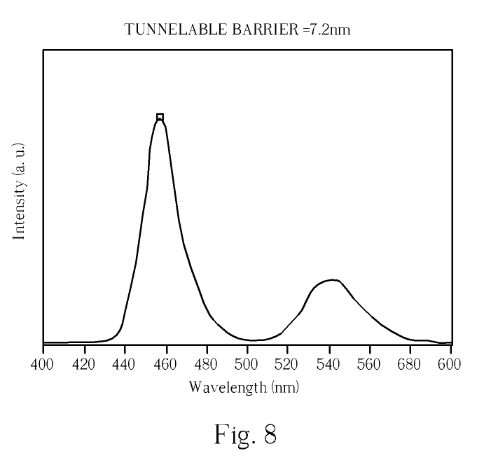

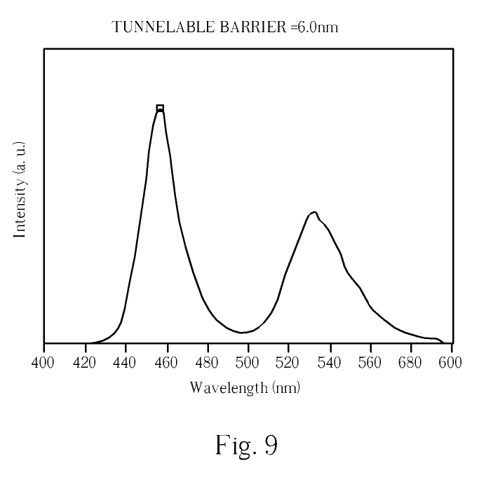

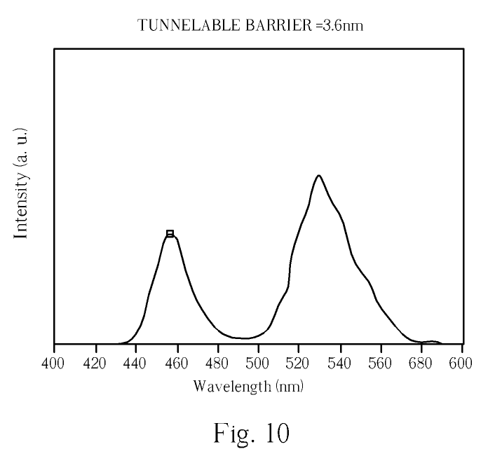

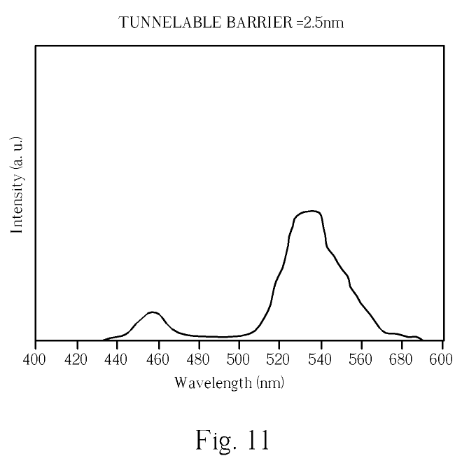

The first quantum well active layer 14 is an active layer of green light with a peak wavelength of about 530 nm, and the second quantum well active layer 16 is an active layer of blue light with a peak wavelength of about 460 nm. In the case that the tunnelable barrier layer 15 has a thickness of 14 nm, there is no obvious tunneling effect happening, and the light mixing LED 1 emits only blue light. Referring to FIG. 7, when the thickness of the tunnelable barrier layer 15 is reduced to 10 nm, the tunneling effect of holes can just be observed. In spite of the mixed light emitted from the light mixing LED 1 is still dominated by blue light generated from the second quantum well active layer 16. However, the tunneled holes contribute a weak green light spectra, and result in the mixed light ranging on the chromaticity chart with a color rendering coordinate of X=˜0.15, Y=˜0.04. Please refer to FIG. 8, when the thickness of the tunnelable barrier layer 15 is reduced to 7.2 nm, holes tunnel through the tunnelable barrier layer 15 obviously, and the green light spectra appear clearly. In this case, the color rendering coordinate of the mixed light is located at X=˜0.164, Y=˜0.199 (refer to FIG. 7). When the thickness of the tunnelable barrier layer 15 is reduced to 6.0 nm, tunnelings become more obvious, so that more holes in a quantum well of blue light tunnel through the tunnelable barrier layer 15 to a quantum well of green light, causing intensity of green light to much enhance (refer to FIG. 9). While the corresponding color rendering coordinate is located at X=˜0.176, Y=˜0.275. When the thickness of the tunnelable barrier layer 15 is reduced to 4.5 nm, intensity of green light is enhanced strongly and even higher than intensity of blue light, and the corresponding color rendering coordinate is shifted to X=˜0.189, Y=˜0.445. When the thickness of the tunnelable barrier layer 15 is further reduced to 3.6 nm, the corresponding color rendering coordinate is shifted to X=˜0.210, Y=˜0.623. The mixed light is much dominated by the green light (refer to FIG. 10). Finally, when the thickness of the tunnelable barrier layer 15 is reduced to 2.5 nm, the majority of holes in the quantum well of blue light tunnel through the tunnelable barrier layer 15, so the wavelength of the mixed light is greatly dominated by the first quantum well active layer 14 (refer to FIG. 11), and the color rendering coordinate is located at X=˜0.19, Y=˜0.74, which is in a range of green light.

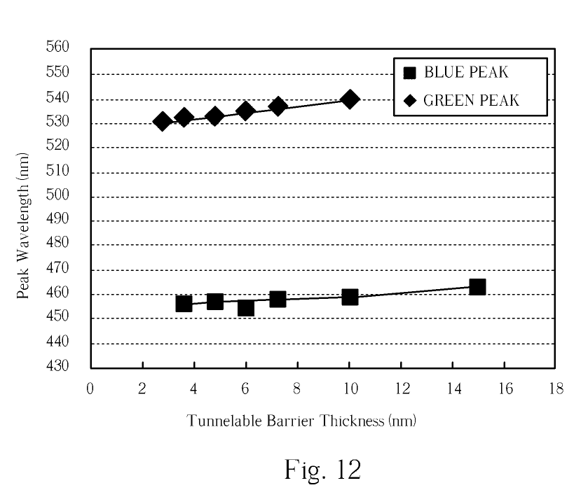

Therefore, by changing the thickness of the tunnelable barrier layer 15, the mixed light can be continuously adjusted in a wide range on the chromaticity diagram. In the light mixing LED 1, when the thickness of the tunnelable barrier layer 15 changed, the wavelengths of the lights emitted from the first and second quantum well active layers 14, 16 will not change too much. Referring to FIG. 12, when the thickness of the tunnelable barrier layer is changed from 2.5 nm to 10 nm, a wavelength shift of blue light is about 6 nm, and a wavelength shift of green light is about 10 nm. Therefore, changing thickness of the tunnelable barrier layer returns a near proportional adjustment of the color rendering coordinate of the mixed light on the chromaticity diagram. That is, the wavelengths of green light and blue light are two points of a (approximate) line in the chromaticity diagram, and the adjustment is along with the line. Therefore, a light mixing LED with desired color can be produced easily.

Besides, in the light mixing LED 1, if the tunnelable barrier layer 15 is doped with Si, the emitted mixed light will have a lower intensity and a shorter wavelength.

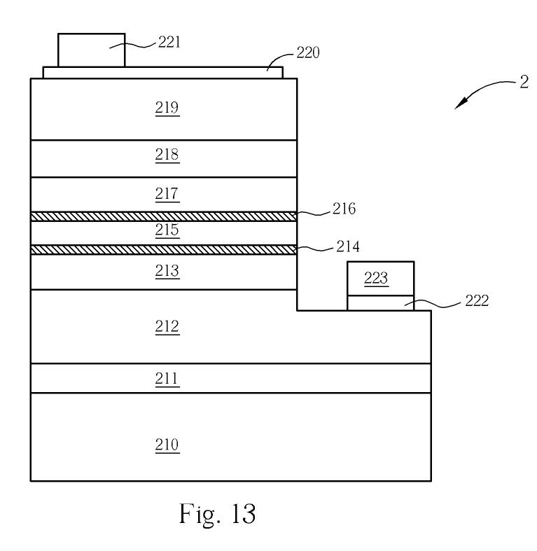

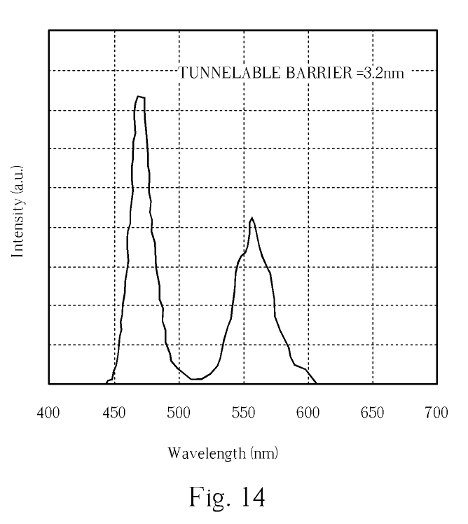

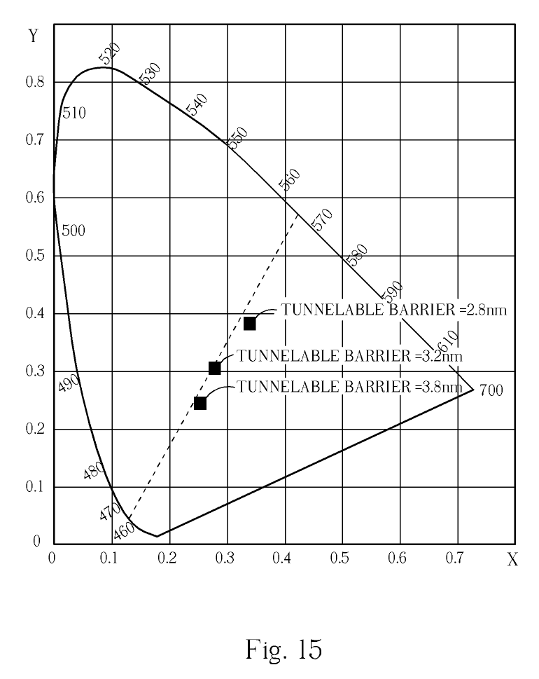

Referring to FIG. 13, it shows a structure of light mixing white LED 2. tThe structure of the light mixing LED 2 is basically the same as the structure of the light mixing LED 1 shown in FIG. 6, except that the first quantum well active layer 14 of the light mixing LED 1 is replaced by a first quantum well active layer 214 of yellow light with a peak wavelength of ˜565 nm, and the second quantum well active layer 16 of the light mixing LED 1 is replaced by a second quantum well active layer 216 of blue light with a peak wavelength of ˜465 nm. Referring to FIGS. 14 and 15, in case that a thickness of a tunnelable barrier layer 215 is 3.2 nm, the light mixing LED 2 can be demonstrated as a white LED with a color rendering coordinate in a white light range of X=˜0.28, Y=˜0.30. Moreover, if the thickness of the tunnelable barrier layer 215 is reduced to 2.8 nm, the color rendering coordinate can be shifted to X=˜0.34, Y=˜0.38, in a range of warm white light. Furthermore, if the thickness of the tunnelable barrier layer 215 is increased to 3.8 nm, the color rendering coordinate is shifted to X=˜0.26, Y=˜0.24, in a range of cold white light.

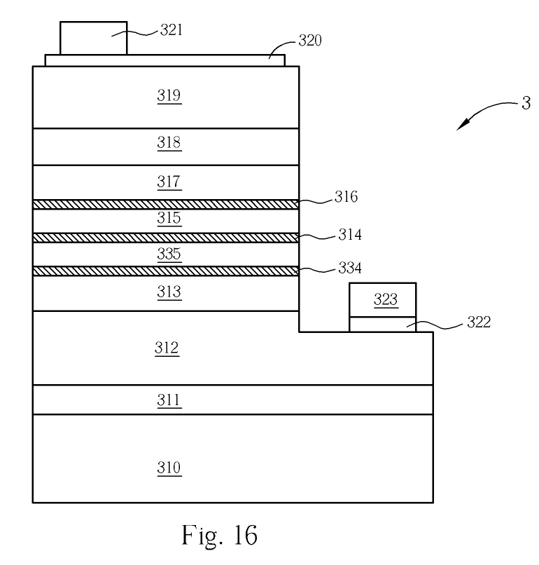

Another embodiment of light mixed LED 3 is illustrated in FIG. 16, which provides three color lights for light mixing. The structure of light mixed LED 3 is basically similar to light mixed LED 1 except by inserting one additional InGaN quantum well active layer 334 of red light and one GaN tunnelable barrier layer 335 between the first barrier layer 313 and the first InGaN quantum well active layer 314. By adjusting the tunnelable barriers 315 and 335, the intensity ratio between the blue, green and red lights can be changed. As a result, the light mixing LED 3 can emit any predetermined color light.

Furthermore, the present invention can increase luminance efficiency by increasing pair numbers of the quantum wells.

In the present invention, a quantum well with a long wavelength can be achieved by increasing the In composition of the InGaN layer, or by incorporating n-type and/or p-type impurity, such as Si, Mg, Zn, etc. in the quantum well as a recombination center for holes and electrons.

Certainly, other quantum well active layers of different colors can be added into the embodiments of the present invention, as long as an energy bandgap of an active layer adjacent to a p-type semiconductor side is larger than an energy bandgap of an active layer adjacent to an n-semiconductor side.

In the present invention, a principal surface of the sapphire substrate comprises a material selected from a group consisting of C-, R-, A-, M-face, etc., and the substrate comprises an insulating material selected from a group consisting of spinel (MgAl2O4), LiGaO2, LiAlO2, etc., or a conductive material selected from a group consisting of GaN, SiC, ZnO, Si, Ge, AlN, GaAs, InP, and GaP. The buffer layer comprises a material selected from a group consisting of binary, trinary, or quaternary AlInGaN. The n-contact layer comprises a material selected from a group consisting of binary, trinary, or quaternary AlInGaN. The barrier layers comprises a material selected from a group consisting of binary, trinary, or quaternary AlInGaN, which can be n-type doped or undoped. The quantum well active layer comprises a material selected from a group consisting of binary, trinary, or quaternary AlInGaN, and must comprises In. The tunnelable barrier layer comprises a material selected from a group consisting of binary, trinary, or quaternary AlInGaN, whose energy bandgap is greater than energy bandgaps of quantum well active layers beside it, and which can be n-type doped or undoped. The p-cladding layer comprises a material selected from a group consisting of binary, trinary, or quaternary AlInGaN. The p-contact layer comprises a material selected from a group consisting of binary, trinary, or quaternary AlInGaN. The transparency contact layer comprises a material selected from a group consisting of Ni/Au, NiO/Au, Ta/Au, TiWN, indium tin oxide, cadmium tin oxide, antimony tin oxide, zinc oxide, and zinc tin oxide. The ohmic metal contact layer comprises a material selected from a group consisting of Al, Ti, Ti/Al, Cr/Al, Ti/Au, Cr/Au, Au/Ge, TiW, WSi, indium tin oxide, cadmium tin oxide, antimony tin oxide, zinc oxide, and zinc tin oxide. The n-electrode pad and the p-electrode pad can be Au, Al, or other substitute materials.

The present invention adjusts color of the mixed light by changing the thickness of the tunnelabe barrier layer. In comparison, in JP 11-87773, energy bandgaps of both the barrier layer and the quantum well layer adjacent to the p-type semiconductor side must be smaller than energy bandgaps of both the barrier layer and the quantum well layer adjacent to the n-type semiconductor side. However, the present invention controls color of the mixed light by controlling density of holes, so that the active layer of a long wavelength is near the n-type semiconductor side, and the active layer of a short wavelength is near the p-type semiconductor side.

Also, in U.S. Pat. No. 6,163,038, the thickness of the barrier layer is 10-200 nm, basically which doesn't disclose the tunneling concept. In this thickness range, the tunneling probability is quite low or even forbidden. Consequently the color of the mixed light cannot be effectively adjusted by changing the thickness of the barrier layer in the disclosed thickness range.

Furthermore, in U.S. Pat. No. 6,608,330, it is necessary to arrange the quantum well of a short wavelength is adjacent to the n-type semiconductor side, while the quantum well of a long wavelength is adjacent to the p-type semiconductor side to achieve its invention purpose. Also, the thickness of the barrier layer disclosed in U.S. Pat. No. 6,608,330 is around hundreds of angstroms, which basically doesn't disclose the tunneling concept and the thickness of the barrier is too thick for tunneling. Consequently the color of the mixed light cannot effectively be adjusted by changing the thickness of the barrier layer.

In sum, the present invention can simplify the manufacturing of white LEDs, and can be utilized for manufacturing light mixing LEDs of any color. Also, the present invention is not limited to LEDs having two quantum well active layers.

Although the various aspects of the present invention have been described with respect to its preferred embodiments, it will be understood that the invention is to be limited only by the scope of the appended claims.

What is claimed is:

1. A light mixing LED comprising:
an n-type nitride-based semiconductor stack layer;
a p-type nitride-based semiconductor stack layer; and
multiple active layers of quantum well structure, sandwiched between the n-type nitride-based semiconductor stack layer and the p-type nitride-based semiconductor stack layer, wherein the multiple active layers comprising:
a first active layer containing In laminated adjacent to the n-type nitride-based semiconductor stack layer;
a second active layer containing In laminated adjacent to the p-type nitride-based semiconductor stack layer, wherein a first principal peak wavelength of light emitted from the first active layer is longer than a second principal peak wavelength of light emitted from the second active layer; and
a tunnelable barrier layer formed between the first active layer and the second active layer,
wherein a color rendering coordinate of a mixed light in a chromaticity diagram is set at a predetermined value in a range between that of the first principal peak wavelength and that of the second principal peak wavelength substantially in proportion to a thickness of the tunnelable barrier layer.

2. The light mixing LED of claim 1, wherein the thickness of the tunnelable barrier is between 2.5 nm and 10 nm.

3. The light mixing LED of claim 1, wherein the first principal peak wavelength is in a range between 440 nm and 500 nm, and the second principal peak wavelength is in a range between 520 nm and 650 nm.

4. The light mixing LED of claim 1, wherein the first active layer comprises a quantum well structure with r1 quantum wells, wherein r1 is greater than 0.

5. The light mixing LED of claim 1, wherein the second active layer comprises a quantum well structure with r2 quantum wells, wherein r2 is greater than 0.

6. The light mixing LED of claim 1, wherein the tunnelable barrier layer comprises an undoped layer.

7. The light mixing LED of claim 1, further comprising a third active layer formed between the first active layer and the n-type semiconductor stack layer, and a second tunnelable barrier layer formed between the first active layer and the third active layer, wherein a third principal peak wavelength of the third active layer is longer than that of the first principal peak wavelength.
